(19) United States
(12) Patent Application Publication
(10) Pub. No.: US 2022/0140048 A1
(43) Pub. Date: May 5, 2022

(54) DISPLAY PANEL, METHOD FOR PREPARING THE SAME, AND DISPLAY DEVICE

(71) Applicant: BOE TECHNOLOGY GROUP CO., LTD., Beijing (CN)

(72) Inventors: Kui ZHANG, Beijing (CN); Li LIU, Beijing (CN); Pengcheng LU, Beijing (CN); Yunlong LI, Beijing (CN)

(73) Assignee: BOE TECHNOLOGY GROUP CO., LTD., Beijing (CN)

(21) Appl. No.: 17/259,050

(22) PCT Filed: Mar. 31, 2020
(86) PCT No.: PCT/CN2020/082463

§ 371 Date: Jan. 8, 2021

(51) Int. Cl. H01L 27/32; H01L 51/52; H01L 51/56

(52) U.S. Cl. CPC H01L 27/3276; H01L 2227/323; H01L 51/56; H01L 51/5271

(57) ABSTRACT

The present disclosure provides a display panel, including: a base substrate, a plurality of metal lead layers located on the base substrate, an insulating layer covering the plurality of metal lead layers, a driving transistor embedded on the base substrate, and a first electrode layer located on a surface of the insulating layer away from the base substrate, a binding area of the display panel including a first via hole exposing a first metal lead layer in the plurality of metal lead layers, a display area of the display panel including a second via hole penetrating the insulating layer, the first electrode layer being electrically connected to a first electrode of the driving transistor through the second via hole, and a slope angle of a sidewall of the first via hole being less than a slope angle of a sidewall of the second via hole.

### CROSS-REFERENCE TO RELATED APPLICATION

This application is the U.S. national phase of PCT Application No. PCT/CN2020/082463 filed on Mar. 31, 2020, which is incorporated herein by reference in its entirety.

### TECHNICAL FIELD

The present disclosure relates to the field of display technology, in particular to a display panel, a method for preparing the same, and a display device.

### BACKGROUND

Silicon-based organic light emitting diodes are micro-displays developed in recent years. With mature silicon-based semiconductor manufacturing processes, organic light emitting diode displays with high display density and high refresh rate can be prepared for use in virtual reality or augmented reality.

### SUMMARY

The embodiment of the present disclosure provides a display panel, a method for preparing the same, and a display device.

In one aspect, a display panel is provided, including: a base substrate, a plurality of metal lead layers located on the base substrate, an insulating layer covering the plurality of metal lead layers, a driving transistor embedded on the base substrate, and a first electrode layer located on a surface of the insulating layer away from the base substrate, a binding area of the display panel including a first via hole exposing a first metal lead layer in the plurality of metal lead layers, a display area of the display panel including a second via hole penetrating the insulating layer, the first electrode layer being electrically connected to a first electrode of the driving transistor through the second via hole, and a slope angle of a sidewall of the first via hole being less than a slope angle of a sidewall of the second via hole.

In some embodiments, the first metal lead layer among the plurality of metal lead layers has a farthest distance from the base substrate.

In some embodiments, the slope angle of the sidewall of the first via hole is greater than or equal to 40° and less than or equal to 70°.

In some embodiments, the first electrode layer includes a plurality of first electrode patterns independent of each other, and a plurality of grooves is arranged on a surface of the insulating layer away from the base substrate, and an orthogonal projection of each groove on the base substrate coincides with an orthogonal projection of a gap between adjacent first electrode patterns on the base substrate.

In some embodiments, the display area of the display panel further includes a reflective layer located between the first metal lead layer and the first electrode layer, the reflective layer comprises a plurality of reflection patterns independent of each other, the plurality of reflection patterns corresponds to the plurality of first electrode patterns respectively, there is an overlapping region between an orthogonal projection of each reflection pattern on the base substrate and an orthogonal projection of a corresponding first electrode pattern on the base substrate, and the orthogonal projection of each reflection pattern on the base substrate does not overlap an orthogonal projection of the second via hole on the base substrate.

In some embodiments, an outer contour of the orthogonal projection of each reflection pattern on the base substrate surrounds an outer contour of the orthogonal projection of the corresponding first electrode pattern on the base substrate.

In some embodiments, the insulating layer includes a first insulating sublayer located between the reflective layer and the first metal lead layer, and a second insulating sublayer located on a surface of the reflective layer away from the first metal lead layer.

In some embodiments, the second via hole is filled with an electrically conductive pillar for connecting each first electrode pattern and the first electrode of the driving transistor.

An embodiment of the present disclosure further provides a display device including the display panel as described above.

An embodiment of the present disclosure further provides a method for preparing a display panel, including:

forming a plurality of metal lead layers and an insulating layer covering the plurality of metal lead layers on a base substrate, and a driving transistor being embedded on the base substrate;

etching the insulating layer in a display area to form a second via hole penetrating the insulating layer;

etching the insulating layer in a binding area to form a first via hole exposing a first metal lead layer in the plurality of metal lead layers, a slope angle of a sidewall of the first via hole being less than a slope angle of a sidewall of the second via hole; and

forming a first electrode layer on a surface of the insulating layer away from the base substrate, the first electrode layer being electrically connected to a first electrode of the driving transistor through the second via hole.

In some embodiments, the method further includes:

forming an electrically conductive pillar in the second via hole.

In some embodiments, the forming the first electrode layer includes:

forming a plurality of first electrode patterns independent of each other, each of the plurality of first electrode patterns being electrically connected to the first electrode of the driving transistor through the electrically conductive pillar.

In some embodiments, the method further includes:

forming a reflective layer located between the first electrode layer and the first metal lead layer, in which the reflective layer comprises a plurality of reflection patterns independent of each other, the plurality of reflection patterns corresponds to the plurality of first electrode patterns respectively, there is an overlapping region between an orthogonal projection of each reflection pattern on the base substrate and an orthogonal projection of a corresponding first electrode pattern on the base substrate, and the orthogonal projection of each reflection pattern on the base substrate does not overlap an orthogonal projection of the second via hole on the base substrate.

### BRIEF DESCRIPTION OF THE DRAWINGS

FIG. 1 is a schematic view showing a display panel in the related art;

FIGS. 2 to 8 are schematic view showing the process for preparing the display panel according to the embodiments of the present disclosure; and

FIG. 9 is a schematic view showing a structure of a display device according to an embodiment of the present disclosure.

### DETAILED DESCRIPTION

In order to make the technical problems to be solved, the technical solutions, and the advantages of the examples of the present disclosure clearer, the present disclosure will be described hereinafter in conjunction with the drawings and specific examples.

The process for preparing a silicon-based OLED (organic light emitting diode) display device is divided into a former stage and a latter stage. The former stage is to prepare the first electrode layer of the OLED display device on the base substrate to obtain the display panel; and the latter stage is to prepare the light emitting layer, the second electrode layer, the encapsulation layer, the color film layer and the encapsulation cover plate, etc., on the display substrate, and to bind the PCB (printed circuit board) and/or FPC (flexible circuit board) to the display panel.

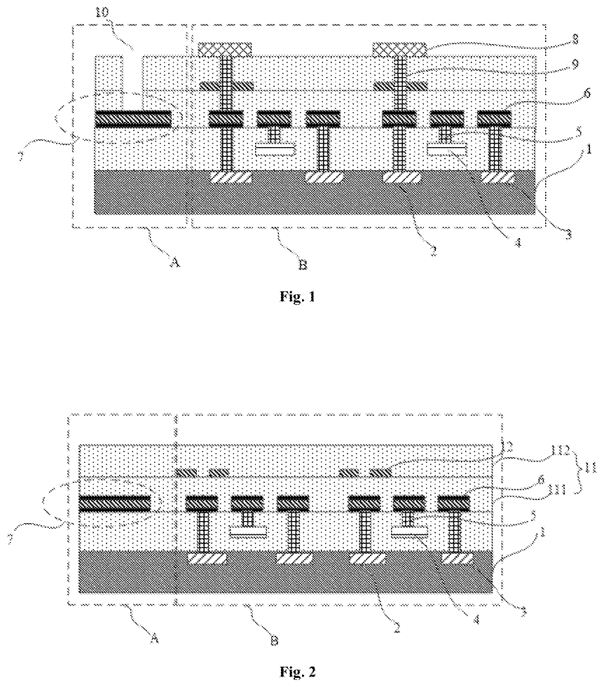

Among them, in order to realize the binding of the PCB and/or FPC with the display panel, the binding pins of the display panel need to be exposed. As shown in FIG. 1, the display panel includes a base substrate 1 and a plurality of metal lead layers arranged on the base substrate 1, in which reference number 6 refers to the first metal lead layer farthest from the base substrate 1, and the first metal lead layer 6 includes binding pins 7 located in binding area A. The display panel includes an insulating layer covering the first metal lead layer 6. In order to expose the binding pins 7, the insulating layer needs to be etched to remove the insulating layer above the binding pins 7, thereby realizing the external input of electrical signals; however, in the related art, a dry etching process with a high aspect ratio is used to etch the insulating layer, and the slope angle of the sidewall of the formed via hole 10 is close to 90°. When the first electrode layer is subsequently formed on the base substrate 1, the first electrode layer in the binding area A needs to be removed. When the pattern of the first electrode layer is formed, the photoresist is first coated on the first electrode layer, then the photoresist is exposed and developed to form the photoresist retention area and the photoresist removal area, and after that the first electrode layer is etched by using the photoresist pattern as a mask. Since all the first electrode layers of the binding area A need to be removed, and the photoresist in the binding area A should be removed. However, since the slope angle of the sidewall of the via hole 10 is close to 90°, the exposure light will be blocked, resulting in the photoresist in the via hole 10 not being effectively exposed. Thus, the subsequent etching will cause the first electrode layer to remain in the via hole 10, resulting in a short circuit between the adjacent binding pins 7, thereby affecting the yield of the silicon-based OLED display device.

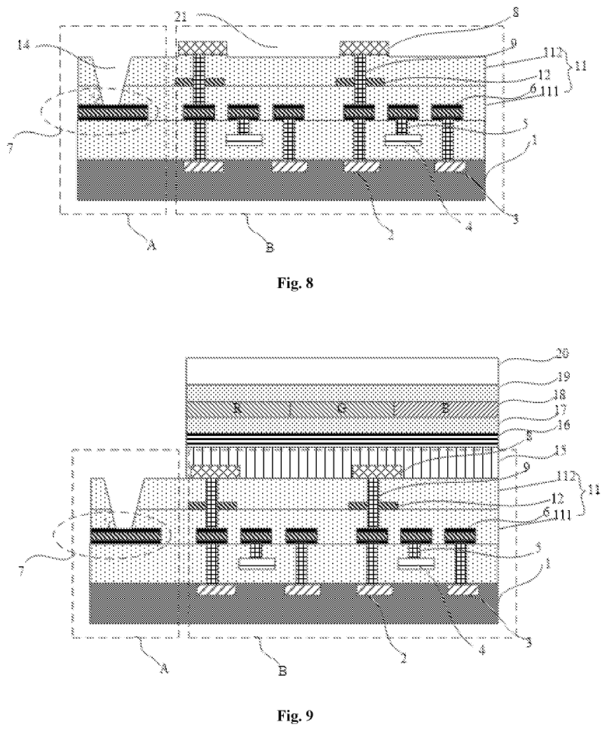

An embodiment of the present disclosure provides a display panel. As shown in FIG. 7, the display panel includes a base substrate 1, a plurality of metal lead layers located on the base substrate 1, and a first electrode layer, in which the first electrode layer includes a plurality of the first electrode patterns 8 independent of each other. A driving transistor is provided in the base substrate 1, in which reference number 2 refers to the source electrode of the driving transistor and reference number 3 refers to the drain electrode of the driving transistor. A plurality of metal lead layers and an insulating layer 11 covering the plurality of metal lead layers are formed on the base substrate 1. FIG. 7 only shows the first metal lead layer 6. The first metal lead layer 6 among the plurality of metal lead layers may be the farthest from the base substrate 1, in which the first metal lead layer 6 is connected to the first electrode of the driving transistor through the electrically conductive connecting line 5. The first electrode may be the source electrode 2, the drain electrode 3 and the polysilicon gate electrode 4 of the driving transistor, and the polysilicon gate electrode 4 is one layer of polysilicon grown by molecular beam epitaxy, in which the layer is conductive and can be used as the gate electrode of a thin film transistor.

The display panel includes a display area B and a binding area A, in which the part of the first metal lead layer 6 located in the binding area A is the binding pin 7. For subsequent binding with the PCB and/or FPC, the binding pin 7 needs to be exposed.

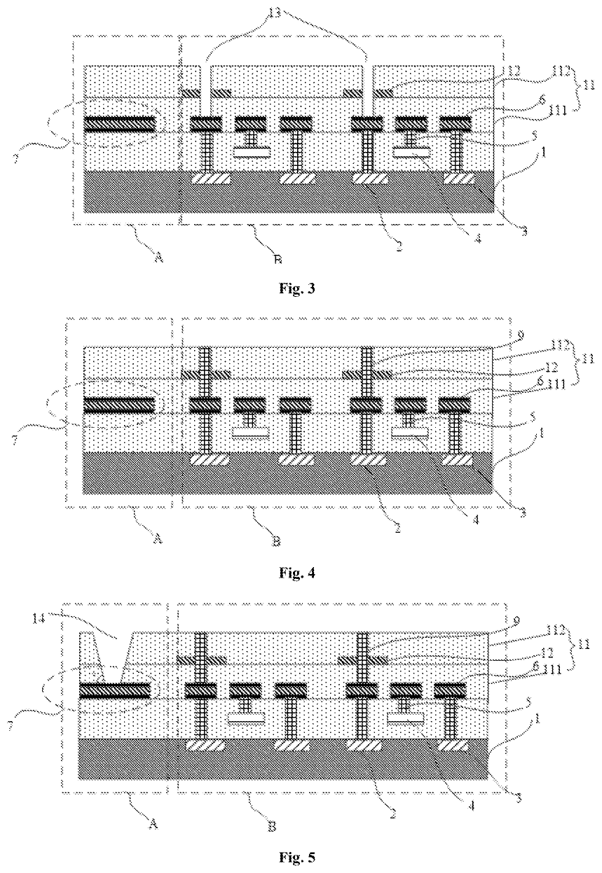

A binding area A of the display panel includes a first via hole 14 exposing the first metal lead layer 6. As shown in FIG. 3, a display area B of the display panel includes a second via hole 13 penetrating through the insulating layer 11, in which the first electrode layer located on a surface of the insulating layer 11 away from the base substrate 1 is connected to the first electrode of the driving transistor through the second via hole 13. A slope angle of the sidewall of the first via hole 14 is less than a slope angle of the sidewall of the second via hole 13.

In this embodiment, the slope angle of the sidewall of the first via hole 14 in the binding area A is less than the slope angle of the sidewall of the second via hole 13 in the display area B, so that the slope angle of the sidewall of the first via hole 14 in the binding area A is relatively small. In the process of forming the first electrode pattern 8, when the photoresist coated on the binding area A is exposed, the shielding of the sidewall of the first via hole 14 to the exposure light can be reduced, so that the photoresist in the first via hole 14 is effectively exposed, and no photoresist remains in the first via hole 14 after the development. When the first electrode material in the first via hole 14 is etched subsequently, the first electrode material in the first via hole 14 can be effectively removed to avoid short circuits between adjacent binding pins 7, thereby ensuring the yield of the silicon-based OLED display device.

In this embodiment, the base substrate 1 may specifically be made of a wafer.

In order to ensure that the photoresist in the first via hole 14 is effectively exposed and no photoresist remains in the first via hole 14 after the development, the slope angle of the sidewall of the first via hole 14 can be less than or equal to 70°. In this way, when the photoresist coated on the binding area A is exposed, the shielding of the sidewall of the first via hole 14 to the exposed light can be prevented, so that the photoresist in the first via hole 14 is effectively exposed, and the photoresist in a via hole 14 is completely removed after the development. When the first electrode material in the first via hole 14 is subsequently etched, the first electrode material in the first via hole 14 can be completely removed. The pore size of the first via hole 14 should not be set too large. If the pore size of the first via hole 14 exceeds the distance between the adjacent binding pins 7, it will affect the binding of the binding pins 7 to the PCB and/or FPC. Therefore, the slope angle of the sidewall of the first via hole 14 may be greater than or equal to 40°, so that the pore size of the first via hole 14 will not be too large.

As shown in FIG. 7, the first electrode pattern 8 is connected to the first metal lead layer 6 of the display area B through the second via hole 13, the first metal lead layer 6 is connected to the first electrode of the driving transistor, the second via hole 13 is filled with an electrically conductive pillar 9 connecting the first electrode pattern 8 and the first metal lead layer 6, the first electrode pattern 8 is connected to the first metal lead layer 6 of the display area B through the electrically conductive pillar 9, and the input electrical signals are received, in which the electrically conductive pillar 9 can be made of tungsten.

When the first electrode material layer is etched to form the first electrode pattern 8, in order to ensure that the first electrode material layer in the region where the first electrode pattern 8 is not required to be formed is completely removed, it can be over-etched to a certain degree. As shown in FIG. 8, in this way, a plurality of grooves 21 are formed on the surface of the insulating layer 11 away from the base substrate 1, and an orthogonal projection of the groove 21 on the base substrate 1 does not exceed an orthogonal projection of the gap between the adjacent first electrode patterns 8 on the base substrate 1, and the orthogonal projection of the groove 21 on the base substrate 1 may coincide with the orthogonal projection of the gap between the adjacent first electrode patterns 8 on the base substrate 1. The existence of the groove 21 does not affect the performance of the display panel, and the depth of the groove 21 can be controlled within 500 angstroms.

The first electrode pattern 8 can be made of ITO or Al alloy, and its thickness can be in a range from 400 to 700 angstroms. The first electrode pattern 8 is transparent. In this way, when the display device performs display, the light emitted by the light emitting layer 15 will pass through the first electrode pattern 8. In order to increase the light extraction efficiency, a display area B of the display panel is also provided with a reflective layer between the metal lead layer 6 and the first electrode layer. As shown in FIG. 7, the reflective layer includes a plurality of reflection patterns 12 independent of each other, in which the reflection patterns 12 correspond to the first electrode patterns 8 in one-to-one manner. There is an overlapping region between the orthogonal projection of the reflective pattern 12 on the base substrate 1 and the orthogonal projection of the corresponding first electrode pattern 8 on the base substrate 1. The reflective pattern 12 can reflect the light transmitted through the first electrode pattern 8 to the light emitting side, thereby increasing the light extraction efficiency of the display device. In order to avoid the second via hole 13, the orthogonal projection of the reflection pattern 12 on the base substrate 1 does not overlap the orthogonal projection of the second via hole 13 on the base substrate 1.

The reflection pattern 12 may be made of metal with high reflectivity, for example, made of Al, and the thickness may be in a range from 50 to 350 angstroms. The reflection pattern 12 does not participate in electric conduction, and will not affect the performance of the display panel.

In order to effectively reflect the light transmitted through the first electrode pattern 8, an outer contour of the orthogonal projection of the reflection pattern 12 on the base substrate 1 may surround the orthogonal projection of the corresponding first electrode pattern 8 on the base substrate 1. However, the area of the reflection pattern 12 should not be set too large, which will waste the material of the reflection pattern 12. Therefore, the outer contour of the orthogonal projection of the reflection pattern 12 on the base substrate 1 can coincide with the outer contour of the orthogonal projection of the first electrode pattern 8 on the base substrate 1, so that the light transmitted through the first electrode pattern 8 can be effectively reflected without causing unnecessary waste.

Since the reflection pattern 12 is made of conductive material, in order to ensure the insulation between the reflection pattern 12 and the first metal lead layer 6 as well as the first electrode pattern 8, as shown in FIG. 7, the insulating layer 11 includes a first insulating sublayer 111 located between the reflective layer and the first metal lead layer 6, and a second insulating sublayer 112 located on a surface of the reflective layer away from the first metal lead layer 6. Among them, the first insulation sublayer 111 may be made of silicon nitride, silicon oxide, or silicon oxynitride, and its thickness is in a range from 500 to 5000 angstroms; and the second insulation sublayer 112 may be made of silicon nitride, silicon oxide, or silicon oxynitride, and the thickness may be set as need and specifically in a range from 1000 to 15000 angstroms.

An embodiment of the present disclosure further provides a method for preparing a display panel, including:

forming a plurality of metal lead layers and an insulating layer covering the plurality of metal lead layers on a base substrate, and a driving transistor being embedded on the base substrate;

etching the insulating layer in a display area to form a second via hole penetrating the insulating layer;

etching the insulating layer in a binding area to form a first via hole exposing a first metal lead layer in the plurality of metal lead layers, a slope angle of a sidewall of the first via hole being less than a slope angle of a sidewall of the second via hole; and

A first electrode layer is formed on a surface of the insulating layer away from the base substrate, and the first electrode layer is electrically connected to the first electrode of the driving transistor through the second via hole.

In this embodiment, the slope angle of the sidewall of the first via hole in the binding area is less than the slope angle of the second via hole sidewall in the display area, so that the slope angle of the sidewall of the first via hole in the binding area is relatively small. Afterwards, in the process of removing the first electrode material in the binding area, when the photoresist coated on the binding area is exposed, the shielding of the sidewall of the first via hole to the exposed light is reduced, so that the first photoresist in the via hole is effectively exposed. After the development, no photoresist remains in the first via hole, when the first electrode material in the first via hole is subsequently etched, the first electrode material within the first via hole can be effectively removed, thereby avoiding short circuits between adjacent binding pins and ensuring the yield of the silicon-based OLED display device.

In a specific embodiment, the method for preparing the display panel includes the following steps.

Step 1. As shown in FIG. 2, a plurality of metal lead layers is formed on the base substrate 1, and the plurality of metal lead layers includes a first metal lead layer 6.

FIG. 2 only shows the first metal lead layer 6 furthest from the base substrate 1, in which the first metal lead layer 6 is connected to the source electrode 2, the drain electrode 3 and the polysilicon gate electrode 4 of the driving transistor through the electrically conductive connecting line 5. The polysilicon gate electrode 4 is one layer of polysilicon grown by molecular beam epitaxy, which is conductive and can be used as the gate electrode of the thin film transistor.

The display panel includes a display area B and a binding area A, in which the part of the first metal lead layer 6 located in the binding area A is the binding pin 7. For subsequent binding with the PCB and/or FPC, the binding pin 7 needs to be exposed.

The first metal lead 6 can be made of a metal with good electrical conductivity, and the thickness is generally in a range from 300 to 5000 angstroms, and specifically can be 350 angstroms.

Step 2. As shown in FIG. 2, a first insulation sublayer 111 covering the first metal lead layer 6 is formed.

The first insulation sublayer 111 may be made of silicon nitride, silicon oxide, or silicon oxynitride, and its thickness may be in a range from 500 to 5000 angstroms.

Step 3. As shown in FIG. 2, a reflection pattern 12 is formed.

In order to increase the light extraction efficiency, a reflective layer can be further formed in the display area B of the display panel. The reflective layer includes a plurality of reflective patterns 12 independent of each other, in which the reflection patterns 12 correspond to the first electrode patterns 8 of the display panel in one-to-one manner. There is an overlapping region between the orthogonal projection of the reflective pattern 12 on the base substrate 1 and the orthogonal projection of the corresponding first electrode pattern 8 on the base substrate 1. The reflective pattern 12 can reflect the light transmitted through the first electrode pattern 8 to the light emitting side to increase the light extraction efficiency of the display device. The reflective pattern 12 does not participate in electric conduction, and the position of the reflective pattern 12 needs to avoid the region where the via hole is to be formed.

Step 4. As shown in FIG. 2, a second insulation sublayer 112 is formed.

The second insulation sublayer 112 may be made of silicon nitride, silicon oxide, or silicon oxynitride, and the thickness may be set as need and specifically may be in a range from 1000 to 15000 angstroms.

Step 5. As shown in FIG. 3, the insulating layer 11 in the display area B is etched to form a second via hole 13.

The first insulating sublayer 111 and the second insulating sublayer 112 constitute the insulating layer 11. Specifically, the insulating layer 11 may be dry-etched to form the second via hole 13, and the second via hole 13 exposes the first metal lead layer 6 in the display area B. An orthogonal projection of the reflection pattern 12 on the base substrate 1 does not overlap an orthogonal projection of the second via hole 13 on the base substrate 1.

Step 6. As shown in FIG. 4, an electrically conductive pillar 9 is formed in the second via hole 13.

Specifically, tungsten powder may be filled in the second via hole 13 to form the electrically conductive pillar 9, and then the surface of the insulating layer 11 may be subjected to a chemical mechanical polishing (CMP) smoothing process to ensure the flatness of the surface of the insulating layer 11.

Step 7. As shown in FIG. 5, the insulating layer 11 in the binding area A is etched to form the first via hole 14.

Specifically, the insulating layer 11 may be dry-etched to form the first via hole 14. By controlling the parameters of the dry etching method, the first via hole 14 with slope angleαon the sidewall is formed, where 40°≤α≤70°.

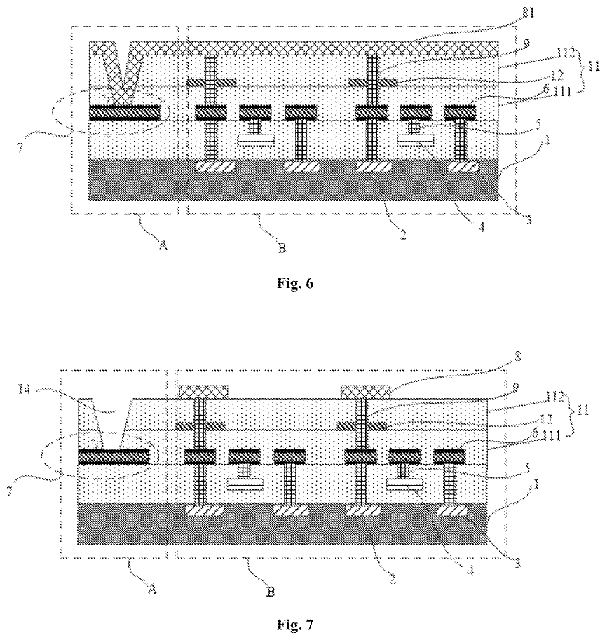

Step 8. As shown in FIG. 6, a first electrode material layer 81 is formed.

The first electrode material layer 81 covers the binding area A and the display area B. The first electrode material layer 81 may be made of ITO or Al alloy, and its thickness may be in a range from 400 to 700 angstroms.

Step 9. As shown in FIG. 7, the first electrode material layer 81 is etched to form a first electrode pattern 8.

First, one layer of photoresist is coated on the first electrode material layer 81, and the photoresist is exposed and developed to form a photoresist retention area and a photoresist removal area, in which the photoresist retention area corresponds to an region where the first electrode pattern 8 is located, and the photoresist in other regions needs to be removed.

The photoresist in the binding area A needs to be exposed. Since 40°≤α≤70°, the sidewall of the first via hole 14 will not shield the exposed light. The photoresist in the first via hole 14 can be effectively exposed, and no photoresist remains in the first via hole 14 after the development. When the first electrode material layer 81 in the first via hole 14 is subsequently etched, the first electrode material layer 81 in the first via hole 14 can be effectively removed. As shown in FIG. 7, the first electrode pattern 8 is formed only in the display area B. Each of the first electrode pattern 8 is connected to the first metal lead layer 6 through an electrically conductive pillar 9, and further connected to the first electrode of the driving transistor through the first metal lead layer 6. The reflection patterns 12 correspond to the first electrode patterns 8 in one-to-one manner, and there is an overlapping region between an orthogonal projection of the reflection pattern 12 on the base substrate 1 and an orthogonal projection of the corresponding first electrode pattern 8 on the base substrate 1.

When the first electrode material layer 81 is etched to form the first electrode pattern 8, in order to ensure that the first electrode material layer 81 in the region where the first electrode pattern 8 is not required to be formed is completely removed, the insulating layer 11 may be over-etched to a certain degree. As shown in FIG. 8, in this way, a plurality of grooves 21 are formed on the surface of the insulating layer 11 away from the base substrate 1, and an orthogonal projection of the grooves 21 on the base substrate 1 does not exceed an orthogonal projection of the gap between the adjacent first electrode patterns 8 on the base substrate 1, and the orthogonal projection of the groove 21 on the base substrate 1 may coincide with the orthogonal projection of the gap between the adjacent first electrode patterns 8 on the base substrate 1. The existence of the groove 21 does not affect the performance of the display panel, and the depth of the groove 21 can be controlled within 500 angstroms.

After the above steps, a display panel with no first electrode material residual on the sidewall of the first via hole 14 can be prepared. When the PCB or FPC is subsequently bonded, it is possible to avoid a short circuit between the adjacent binding pins 7, and ensure the yield of the silicon-based OLED display device.

An embodiment of the present disclosure further provides a display device including the display panel as described above.

The display device includes but is not limited to: a radio frequency unit, a network module, an audio output unit, an input unit, a sensor, a display unit, a user input unit, an interface unit, a memory, a processor, a power supply and other components. Those skilled in the art would understand that the structure of the above display device does not constitute a limitation on the display device, and the display device may include more or less of the above components, or combine some components, or have different component arrangements. In the embodiments of the present disclosure, the display device includes, but is not limited to, a display, a mobile phone, a tablet computer, a television, a wearable electronic device, a navigation display device, or the like.

The display device may be any product or component having a display function, such as a television, a display, a digital photo frame, a mobile phone, a tablet computer, etc., in which the display device further includes a flexible circuit board, a printed circuit board, and a backplane.

As shown in FIG. 9, the display device further includes a light emitting layer 15, a second electrode layer 16, a first encapsulation layer 17, a color film layer 18, a second encapsulation layer 19, and an encapsulation cover plate 20. The color film layer 18 may include a plurality of filter units of different colors, such as a red filter unit R, a green filter unit G, and a blue filter unit B. The color film layer 18 can realize the color display of the display device.

The first encapsulation layer 17 may use one or a combination of SiNX, SiO₂, organic matter, and Al₂O₃. In a specific example, the first encapsulation layer 17 may include SiOx layer, an organic layer and Al₂O₃ layer that are stacked in sequence. The thickness of the first encapsulation layer 17 can be designed as need.

The second encapsulation layer 19 may use one or a combination of SiNX, SiO₂, organic matter, and Al₂O₃. In a specific example, the second encapsulation layer 19 may include SiOx layer, an organic layer and Al₂O₃ layer that are stacked in sequence. The thickness of the second encapsulation layer 19 can be designed as need.

The first electrode layer may be one of the anode layer and the cathode layer, and the second electrode layer may be the other of the anode layer and the cathode layer.

In the method embodiments of the present disclosure, the serial numbers of the steps cannot be used to define the sequence of the steps. As for one skilled in the art, the changes in the order of steps without paying creative work also fall within the scope of the present disclosure.

It should be noted that the various embodiments in this specification are described in a progressive manner, and the same or similar portions between the various embodiments can be referred to each other, and each embodiment focuses on the differences from other embodiments. In particular, for the embodiment, since it is basically similar to the product embodiment, the description is relatively simple, and the relevant parts can be referred to a part of the description of the product embodiment.

Unless otherwise defined, technical terms or scientific terms used herein have the normal meaning commonly understood by one skilled in the art in the field of the present disclosure. The words “first”, “second”, and the like used herein does not denote any order, quantity, or importance, but rather merely serves to distinguish different components. The “including”, “comprising”, or the like used in the present disclosure means that the element or item appeared in front of the word encompasses the element or item and their equivalents listed after the word, and does exclude other elements or items. The word “connected” or “connecting” or the like are not limited to physical or mechanical connections, but may include electrical connections, whether direct or indirect. “On”, “under”, “left”, “right” and the like are only used to represent relative positional relationships, and when the absolute position of the described object is changed, the relative positional relationship may also be changed, accordingly.

It will be understood that when an element, such as a layer, film, region, or substrate, is referred to as being “on” or “under” another element, the element may be directly “on” or “under” another element, or there may be an intermediate element.

In the description of the above embodiments, the specific features, structures, materials or features may be combined in any suitable manner in any one or more embodiments or examples.

The above description is merely the specific embodiment of the present disclosure, but the scope of the present disclosure is not limited thereto. Moreover, any person skilled in the art would readily conceive of modifications or substitutions within the technical scope of the present disclosure, and these modifications or substitutions shall also fall within the protection scope of the present disclosure. Therefore, the protection scope of the present disclosure should be determined by the scope of the claims.

1. A display panel, comprising: a base substrate, a plurality of metal lead layers located on the base substrate, an insulating layer covering the plurality of metal lead layers, a driving transistor embedded on the base substrate, and a first electrode layer located on a surface of the insulating layer away from the base substrate, a binding area of the display panel comprising a first via hole exposing a first metal lead layer in the plurality of metal lead layers, a display area of the display panel comprising a second via hole penetrating the insulating layer, the first electrode layer being electrically connected to a first electrode of the driving transistor through the second via hole, and a slope angle of a sidewall of the first via hole being less than a slope angle of a sidewall of the second via hole.

2. The display panel of claim 1, wherein the first metal lead layer among the plurality of metal lead layers has a farthest distance from the base substrate.

3. The display panel of claim 1, wherein the slope angle of the sidewall of the first via hole is greater than or equal to 40° and less than or equal to 70°.

4. The display panel of claim 1, wherein the first electrode layer comprises a plurality of first electrode patterns independent of each other, and a plurality of grooves is arranged on a surface of the insulating layer away from the base substrate, and an orthogonal projection of each groove on the base substrate coincides with an orthogonal projection of a gap between adjacent first electrode patterns on the base substrate.

5. The display panel of claim 4, wherein the display area of the display panel further comprises a reflective layer located between the first metal lead layer and the first electrode layer, the reflective layer comprises a plurality of reflection patterns independent of each other, the plurality of reflection patterns corresponds to the plurality of first electrode patterns respectively, there is an overlapping region between an orthogonal projection of each reflection pattern on the base substrate and an orthogonal projection of a corresponding first electrode pattern on the base substrate, and the orthogonal projection of each reflection pattern on the base substrate does not overlap an orthogonal projection of the second via hole on the base substrate.

6. The display panel of claim 5, wherein an outer contour of the orthogonal projection of each refection pattern on the base substrate surrounds an outer contour of the orthogonal projection of the corresponding first electrode pattern on the base substrate.

7. The display panel of claim 5, wherein the insulating layer comprises a first insulating sublayer located between the reflective layer and the first metal lead layer, and a second insulating sublayer located on a surface of the reflective layer away from the first metal lead layer.

8. The display panel of claim 4, wherein the second via hole is filled with an electrically conductive pillar for connecting each first electrode pattern and the first electrode of the driving transistor.

9. A display device, comprising the display panel of claim 1.

10. A method for preparing a display panel, comprising:
forming a plurality of metal lead layers and an insulating layer covering the plurality of metal lead layers on a base substrate, and a driving transistor being embedded on the base substrate;
etching the insulating layer in a display area to form a second via hole penetrating the insulating layer;
etching the insulating layer in a binding area to form a first via hole exposing a first metal lead layer in the plurality of metal lead layers, a slope angle of a sidewall of the first via hole being less than a slope angle of a sidewall of the second via hole; and
forming a first electrode layer on a surface of the insulating layer away from the base substrate, the first electrode layer being electrically connected to a first electrode of the driving transistor through the second via hole.

11. The method of claim 10, wherein the method further comprises:
forming an electrically conductive pillar in the second via hole.

12. The method of claim 11, wherein the forming the first electrode layer comprises:
forming a plurality of first electrode patterns independent of each other, each of the plurality of first electrode patterns being electrically connected to the first electrode of the driving transistor through the electrically conductive pillar.

13. The method of claim 12, wherein the method further comprises:
forming a reflective layer located between the first electrode layer and the first metal lead layer, wherein the reflective layer comprises a plurality of reflection patterns independent of each other, the plurality of reflection patterns corresponds to the plurality of first electrode patterns respectively, there is an overlapping region between an orthogonal projection of each reflection pattern on the base substrate and an orthogonal projection of a corresponding first electrode pattern on the base substrate, and the orthogonal projection of each reflection pattern on the base substrate does not overlap an orthogonal projection of the second via hole on the base substrate.
